(19) United States
(12) Patent Application Publication
(10) Pub. No.: US 2022/0272865 A1
(43) Pub. Date: Aug. 25, 2022

(54) DUSTPROOF HEAT-DISSIPATING MECHANISM AND ELECTRONIC DEVICE WITH DUSTPROOF HEAT-DISSIPATING MECHANISM

(71) Applicant: CINCOZE CO., LTD., New Taipei City (TW)

(72) Inventor: HSIN-TE CHIEN, New Taipei City (TW)

(21) Appl. No.: 17/320,229

(22) Filed: May 14, 2021

(30) Foreign Application Priority Data
Feb. 19, 2021 (TW) 110105748

(51) Int. Cl. H05K 7/20; G06F 1/20

(52) U.S. Cl. CPC H05K 7/20154; G06F 1/206; H05K 7/20409

(57) ABSTRACT

A dustproof heat-dissipating mechanism includes a casing, a thermally conductive component, a heat-dissipating component and a first fan. A dent portion is disposed on an outer lateral side of the casing and spaced apart from an electronic component storage space. The thermally conductive component is disposed in the casing. One end of the thermally conductive component is connected to the inner lateral side of the dent portion. The heat-dissipating component has a plurality of cooling fins disposed in the dent portion. The first fan is disposed at the dent portion and faces the heat-dissipating component. An electronic device with the dustproof heat-dissipating mechanism and an electronic component is further provided. The dustproof heat-dissipating mechanism is free from dust accumulation and easy to clean.

### CROSS-REFERENCE TO RELATED APPLICATION

This non-provisional application claims priority under 35 U.S.C. § 119(a) on Patent Application No(s). 110105748 filed in Taiwan, R.O.C. on Feb. 19, 2021, the entire contents of which are hereby incorporated by reference.

### BACKGROUND OF THE INVENTION

### 1. Field of the Invention

The present disclosure relates to heat-dissipating mechanisms and electronic devices, and in particular to a dustproof heat-dissipating mechanism and an electronic device with the dustproof heat-dissipating mechanism.

### 2. Description of the Related Art

Commercially-available electronic devices, such as computers, dissipate heat with fans by blowing cool ambient air toward heat-generating components, so as to lower the internal temperature of the electronic devices. However, the introduction of ambient gas into a casing of an electronic device is predisposed to accumulation of dust; as a result, it not only renders heat dissipation difficult but also affects the efficiency of operation of electronic components in the long term. Furthermore, the casing contains too many electronic components to clean conveniently.

### BRIEF SUMMARY OF THE INVENTION

An objective of the present disclosure is to provide a dustproof heat-dissipating mechanism and an electronic device with the dustproof heat-dissipating mechanism.

To achieve at least the above objective, the present disclosure provides a dustproof heat-dissipating mechanism, comprising: a casing having therein an electronic component storage space, wherein a dent portion is disposed on an outer lateral side of the casing and spaced apart from the electronic component storage space; a thermally conductive component disposed in the electronic component storage space and having an end connected to an inner lateral side of the dent portion; a heat-dissipating component having a plurality of cooling fins disposed in the dent portion; and a first fan disposed at the dent portion and facing the heat-dissipating component.

In an embodiment of the present disclosure, the cooling fins disposed in the dent portion are spaced apart by a specific distance and extend in a direction parallel to a lengthwise dimension of the dent portion, wherein the first fan is disposed at an end of the lengthwise dimension.

In an embodiment of the present disclosure, the cooling fins each have a serrate surface.

In an embodiment of the present disclosure, the dustproof heat-dissipating mechanism further comprises a cover panel for covering the outer lateral side.

In an embodiment of the present disclosure, the first fan is removably disposed at the dent portion.

In an embodiment of the present disclosure, the casing has an electrical connection unit disposed at the dent portion, and the first fan is removably connected to the electrical connection unit.

In an embodiment of the present disclosure, the dustproof heat-dissipating mechanism further comprises a second fan disposed at an end of the dent portion, wherein the end of the dent portion is positioned distal to the first fan.

The present disclosure further provides an electronic device with the dustproof heat-dissipating mechanism, comprising: the dustproof heat-dissipating mechanism; and an electronic component disposed in the electronic component storage space. The thermally conductive component has one end connected to an inner lateral side of the dent portion and the other end connected to the electronic component.

According to the present disclosure, the dustproof heat-dissipating mechanism and the electronic device with the dustproof heat-dissipating mechanism have advantages described below. The heat-dissipating component and the first fan not only effectively remove heat from the inside of the casing but are also suitable for the cuboid casing. The storage space inside the casing is hermetically sealed to prevent intrusion of dust into the casing and thereby protect electronic components therein.

### BRIEF DESCRIPTION OF THE DRAWINGS

FIG. 1 is a perspective view of a dustproof heat-dissipating mechanism according to an embodiment of the present disclosure.

FIG. 2 is a bottom view of the dustproof heat-dissipating mechanism according to an embodiment of the present disclosure.

FIG. 3 is a cross-sectional view of an electronic device with the heat-dissipating mechanism according to an embodiment of the present disclosure.

### DETAILED DESCRIPTION OF THE INVENTION

To facilitate understanding of the object, characteristics and effects of this present disclosure, embodiments together with the attached drawings for the detailed description of the present disclosure are provided.

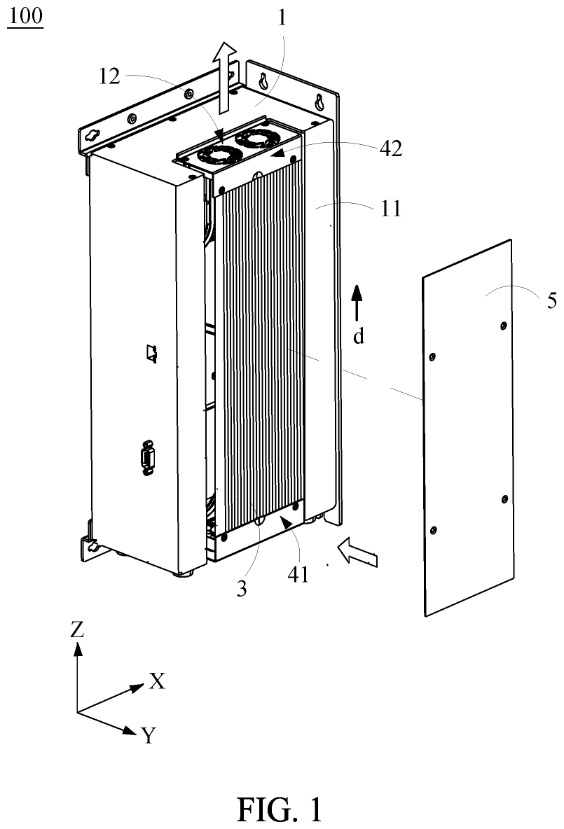

Referring to FIG. 1 through FIG. 3, a dustproof heat-dissipating mechanism 100 provided according to an embodiment of the present disclosure comprises a casing 1, a thermally conductive component 2, a heat-dissipating component 3 and a first fan 41.

The casing 1 has therein an electronic component storage space S for storing an electronic component 6, connection circuits and any other apparatuses required for an electronic device. A dent portion 12 is concavely disposed on an outer lateral side 11 of the casing 1. The electronic component storage space S and dent portion 12 are spaced apart. The casing 1 is made of an insulating material, but the present disclosure is not limited thereto.

Referring to FIG. 3, the thermally conductive component 2 is disposed in the electronic component storage space S of the casing 1. One end 21 of the thermally conductive component 2 is connected to the inner lateral side 121 of the dent portion 12. The other end 22 of the thermally conductive component 2 is connected to the electronic component 6. The electronic component 6 is an active electronic component or passive electronic component. The heat generated by the electronic component 6 is transferred to the dent portion 12 via the thermally conductive component 2. The thermally conductive component 2 is preferably made of a material which transfers heat quickly, such as metal.

Referring to FIG. 1 and FIG. 3, the heat-dissipating component 3 has a plurality of cooling fins 31 disposed in the dent portion 12. The heat transferred by the thermally conductive component 2 to the dent portion 12 is dissipated to the outside with the cooling fins 31. In this embodiment, the cooling fins 31 are made of metal and have serrate surfaces to increase the surface area for heat dissipation. However, the present disclosure is not limited thereto, and thus the cooling fins 31 can be provided in any other forms.

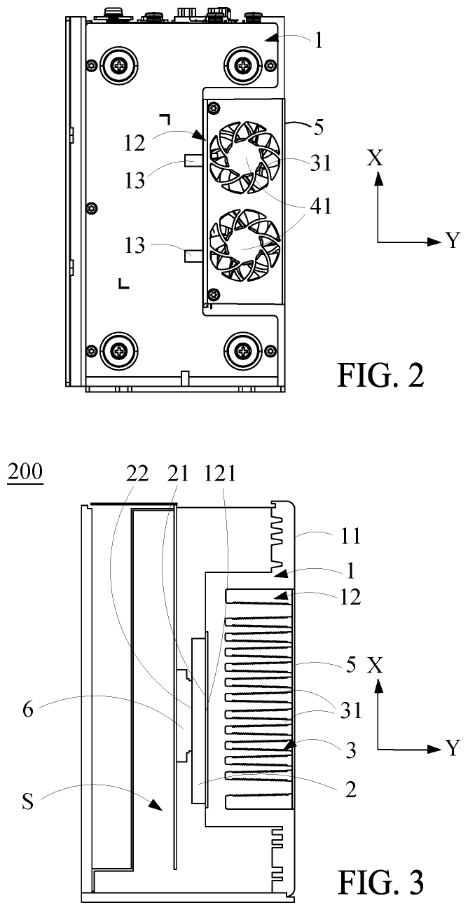

Referring to FIG. 1 and FIG. 2, the first fan 41 is disposed at dent portion 12 and faces heat-dissipating component 3. The first fan 41 blows ambient air into dent portion 12 to remove heat from heat-dissipating component 3. Thus, dent portion 12 provides a unidirectional gaseous channel. The first fan 41 keeps introducing cool air to one end of dent portion 12. The cool air takes up heat and then exits the other end of dent portion 12. The other end of dent portion 12 is positioned distal to the first fan 41.

According to the present disclosure, the dustproof heat-dissipating mechanism 100 has advantages described below. The dent portion 12, heat-dissipating component 3, and first fan 41 are disposed outside storage space S to effectively remove heat from the inside of the casing 1 via the outer side of the casing 1 and are suitable for cuboid casings. The electronic component storage space S inside casing 1 is hermetically sealed to prevent intrusion of dust into the casing 1 and thereby protect electronic components therein.

Referring to FIG. 1 and FIG. 3, a plurality of cooling fins 31 are disposed in dent portion 12, extended in parallel, and spaced apart by a specific distance. The direction in which the cooling fins 31 are extended is parallel to a lengthwise dimension d (i.e., axis Z) of dent portion 12. The first fan 41 is disposed at one end of the lengthwise dimension d. Thus, the space of the dent portion 12 is partitioned by the cooling fins 31 and thus divided into a plurality of narrow spaces which extend along lengthwise dimension d. Air current generated by the first fan 4 flows quickly and unidirectionally within the dent portion 12.

Referring to FIG. 1 and FIG. 3, the dustproof heat-dissipating mechanism 100 further comprises a cover panel 5 for covering the outer lateral side 11 of the casing 1. A space is formed by and between the cover panel 5 and dent portion 12 and is hermetically-sealed except for two open ends of the lengthwise dimension d. Owing to the cover panel 5, the air current generated by the first fan 41 cannot spread laterally on its way, thereby ensuring that the air current can reach the terminal end of the dent portion 12 to remove the heat.

Referring to FIG. 1, the dustproof heat-dissipating mechanism 100 further comprises a second fan 42 disposed at one end of the dent portion 12, wherein the one end of the dent portion 12 is positioned distal to the first fan 41. The second fan 42 blows air in the same direction as the first fan 41; hence, the second fan 42 faces away from the heat-dissipating component 3 and blows air outward. Thus, the purpose of the second fan 42 is to blow air from the dent portion 12 to the outside. The first fan 41 and second fan 42 work together to speed up the flow of the air current.

Additional fans may be disposed at the middle or any other parts of the dent portion 12 to blow air in the aforesaid direction to increase the speed at which the air current passes through the dent portion 12, but the present disclosure is not limited thereto.

In this embodiment, the first fan 41 and second fan 42 are removably disposed at the dent portion 12. Thus, the first fan 41 and second fan 42 can be removed from the dent portion 12 to undergo maintenance or cleaning.

Referring to FIG. 3, the present disclosure further provides an electronic device 200 which comprises the dustproof heat-dissipating mechanism 100 and the electronic component 6. The electronic component 6 is disposed in the electronic component storage space S of the casing 1 and is in the number of one or more (The electronic components 6 are connected in series.) The electronic device 200 is, for example, a computer or any large-sized electronic apparatus which requires heat dissipation.

Referring to FIG. 2, the casing 1 has an electrical connection unit 13 disposed at the dent portion 12, whereas the first fan 41 is removably connected to the electrical connection unit 13. The electrical connection unit 13 is electrically connected to a power supply device (not shown) inside the casing 1. Thanks to the electrical connection unit 13, the power supply to the first fan 41 is completely provided by the electronic device 200 without any external circuits.

While the present disclosure has been described by means of specific embodiments, numerous modifications and variations could be made thereto by those skilled in the art without departing from the scope and spirit of the present disclosure set forth in the claims.

What is claimed is:

1. A dustproof heat-dissipating mechanism, comprising:
a casing having therein an electronic component storage space, wherein a dent portion is disposed on an outer lateral side of the casing and spaced apart from the electronic component storage space;
a thermally conductive component disposed in the electronic component storage space and having an end connected to an inner lateral side of the dent portion;
a heat-dissipating component having a plurality of cooling fins disposed in the dent portion; and
a first fan disposed at the dent portion and facing the heat-dissipating component.

2. The dustproof heat-dissipating mechanism of claim 1, wherein the cooling fins disposed in the dent portion are spaced apart by a specific distance and extend in a direction parallel to a lengthwise dimension of the dent portion, wherein the first fan is disposed at an end of the lengthwise dimension.

3. The dustproof heat-dissipating mechanism of claim 1, wherein the cooling fins each have a serrate surface.

4. The dustproof heat-dissipating mechanism of claim 1, further comprising a cover panel for covering the outer lateral side.

5. The dustproof heat-dissipating mechanism of claim 1, wherein the first fan is removably disposed at the dent portion.

6. The dustproof heat-dissipating mechanism of claim 5, wherein the casing has an electrical connection unit disposed at the dent portion, and the first fan is removably connected to the electrical connection unit.

7. The dustproof heat-dissipating mechanism of claim 1, further comprising a second fan disposed at an end of the dent portion, wherein the end of the dent portion is positioned distal to the first fan.

8. An electronic device with a dustproof heat-dissipating mechanism, comprising:
the dustproof heat-dissipating mechanism of claim 1; and
an electronic component disposed in the electronic component storage space, wherein the thermally conductive component has an end connected to an inner lateral side of the dent portion and another end connected to the electronic component.
